(19) United States
(12) Patent Application Publication
(10) Pub. No.: US 2010/0025690 A1
(43) Pub. Date: Feb. 4, 2010

(54) THIN FILM TRANSISTOR SUBSTRATE AND METHOD OF MANUFACTURING THE SAME

(75) Inventors: Yeon-Ju KIM, Suwon-si (KR); Sung-Hoon Yang, Yongin-si (KR); So-Woon Kim, Suwon-si (KR); So-Hyun Lee, Yongin-si (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/366,178

(22) Filed: Feb. 5, 2009

(30) Foreign Application Priority Data
Jul. 29, 2008 (KR) 10-2008-0073899

(51) Int. Cl. H01L 29/786; H01L 21/336

(52) U.S. Cl. 257/66; 438/158; 257/E29.288; 257/E21.414

(57) ABSTRACT

A thin film transistor substrate includes an insulating plate, a plurality of fan-out lines arranged on the insulating plate and including at least a pair of adjacent fan-out lines, a plurality of signal lines connected to the plurality of fan-out lines, and a plurality of thin film transistors connected to the plurality of signal lines. The adjacent fan-out lines partially overlap with each other, and each overlapping area of the adjacent fan-out lines is the same.

This application claims priority from and the benefit of Korean Patent Application No. 10-2008-0073899, filed on Jul. 29, 2008, which is hereby incorporated by reference for all purposes as if fully set forth herein.

### BACKGROUND OF THE INVENTION

1. Field of the Invention

The invention relates to a thin film transistor substrate, and a method of manufacturing the thin film transistor substrate. More particularly, the invention relates to a thin film transistor substrate that may have an improved display quality, and a method of manufacturing the thin film transistor substrate.

2. Discussion of the Background

In general, a liquid crystal display includes a thin film transistor substrate, an opposite substrate facing the thin film transistor substrate, and a liquid crystal layer disposed between the thin film transistor substrate and the opposite substrate.

The thin film transistor substrate may include a display area in which a plurality of signal lines insulated from each other is arranged. The signal lines may include a plurality of gate lines, and a plurality of data lines insulated from the gate lines. The thin film transistor substrate may include a peripheral area in which a gate driving chip and a data driving chip are arranged. The gate driving chip outputs a gate signal, and the data driving chip outputs a data signal.

The thin film transistor substrate may further include a plurality of gate fan-out lines arranged between the gate driving chip and the plurality of gate lines. The plurality of gate fan-out lines provides the gate signal from the gate driving chip to the plurality of gate lines.

The thin film transistor substrate may further include a plurality of data fan-out lines arranged between the data driving chip and the plurality of data lines. The plurality of data fan-out lines provides the data signal from the data driving chip to the plurality of data lines.

Generally, a distance between two adjacent gate fan-out lines in an area adjacent to the gate driving chip is smaller than a distance between two adjacent gate lines. In addition, a distance between two adjacent data fan-out lines in an area adjacent to the data driving chip is generally smaller than a distance between two adjacent data lines. The plurality of gate fan-out lines may be partially bent and extend from the gate lines to the area adjacent to the gate driving chip. Thus, all the gate fan-out lines may not have same length and resistance. This applies to the data fan-out lines as well.

Recently, the size of the display area of the liquid crystal display has increased as the number of pixels and driving chips increases. The size of the peripheral area, however, has gradually been reduced. As a result, it may be difficult to reduce a length difference and a resistance difference between the fan-out lines.

### BRIEF SUMMARY OF THE INVENTION

The present invention provides a thin film transistor substrate that may have an improved display quality.

The present invention also provides a method of manufacturing the thin film transistor substrate.

Additional features of the invention will be set forth in the description which follows, and in part will be apparent from the description, or may be learned by practice of the invention.

The present invention discloses a thin film transistor substrate including an insulating plate, a plurality of fan-out lines arranged on the insulating plate and including at least a pair of adjacent fan-out lines, a plurality of signal lines connected to the plurality of fan-out lines, and a plurality of thin film transistors connected to the plurality of signal lines. The adjacent fan-out lines partially overlap with each other, and each overlapping area of the adjacent fan-out lines is the same.

The present invention also discloses a thin film transistor substrate including an insulating plate, a plurality of gate fan-out lines arranged on the insulating plate, a plurality of data fan-out lines arranged on the insulating plate, a plurality of gate lines connected to the gate fan-out lines, a plurality of data lines connected to the data fan-out lines, and a plurality of thin film transistors connected to the plurality of gate lines and the plurality of data lines. At least one of the gate fan-out lines and the data fan-out lines includes at least one pair of adjacent fan-out lines, and at least a portion of the adjacent fan-out lines has a zigzag shape.

The present invention also discloses a method of forming a thin film transistor substrate including forming a plurality of gate electrodes, a plurality of gate lines connected to the gate electrodes, a first gate fan-out line extending to one of the gate lines, and a first data fan-out line. A gate insulating layer is formed on the gate electrodes, the gate lines, the first gate fan-out line, and the first data fan-out line. A plurality of semiconductor patterns is formed on the gate insulating layer. A plurality of source electrodes, a plurality of drain electrodes, and a plurality of data lines connected to the source electrodes are formed. The first data fan-out line is connected to one of the data lines, a second gate fan-out line that is adjacent to the first gate fan-out line and connected to one of the gate lines, and a second data fan-out line that is adjacent to the first data fan-out line and extends to one of the data lines. At least a portion of the second gate fan-out line overlaps with at least a portion of the first gate fan-out line. A passivation layer is formed on the source electrodes, the drain electrodes, the data lines, the second gate fan-out line, and the second data fan-out line.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a top view showing a thin film transistor substrate according to an exemplary embodiment of the present invention.

FIG. 2 is a cross-sectional view taken along line II-II′ of FIG. 1.

FIG. 3 is an enlarged top view showing portion ‘A’ of FIG. 1.

FIG. 4 is an enlarged top view showing portion ‘B’ of FIG. 3.

FIG. 5 is a cross-sectional view taken along line V-V′ of FIG. 4.

FIG. 6 is an enlarged top view showing data fan-out lines according to another exemplary embodiment of the invention.

FIG. 7 is a cross-sectional view taken along line VII-VII′ of FIG. 3.

### DETAILED DESCRIPTION OF THE ILLUSTRATED EMBODIMENTS

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on”, “connected to”, or “coupled to” another element, it can be directly on, directly connected to, or directly coupled to the other element or intervening elements may be present therebetween. In contrast, when an element is referred to as being “directly on”, “directly connected to”, or “directly coupled to” another element, there are no intervening elements present. As used herein, the term “and/or” includes any and all combinations of one or more of the associated listed items.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions shown herein but are to include deviations in shapes that result, for example, from manufacturing. For example, a region shown or described as flat may, typically, have rough and/or nonlinear features. Moreover, sharp angles that are shown may be rounded. Thus, the regions shown in the figures are schematic in nature and their shapes are not intended to show the precise shape of a region and are not intended to limit the scope of the present invention.

Hereinafter, exemplary embodiments of the present invention will be explained in further detail with reference to the accompanying drawings.

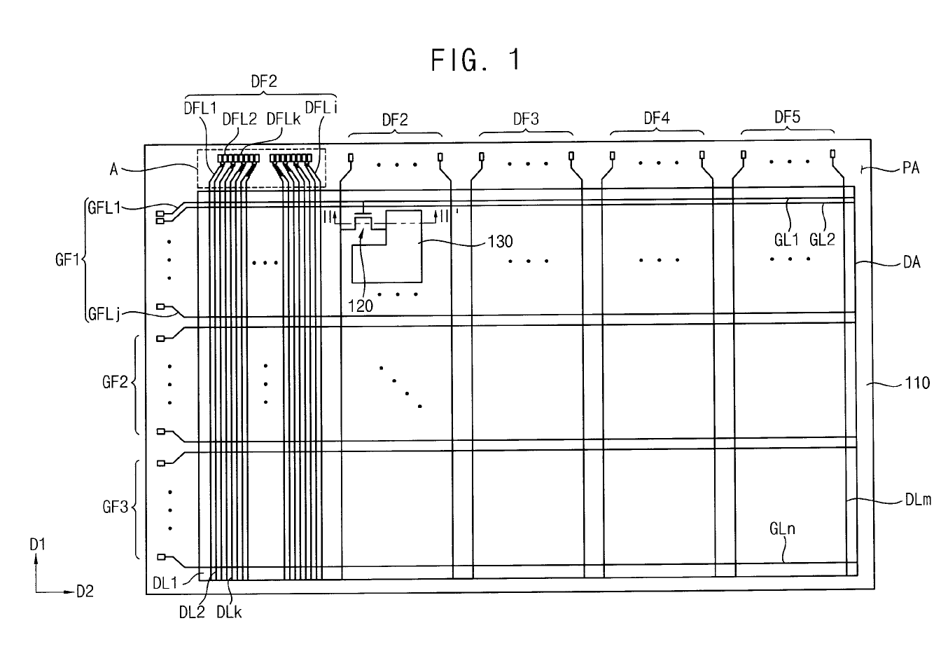

FIG. 1 is a top view showing a thin film transistor substrate according to an exemplary embodiment of the invention. Referring to FIG. 1, a thin film transistor substrate 100 includes an insulating plate 110, a plurality of signal lines including a plurality of data lines DL1-DLm and a plurality of gate lines GL1-GLn formed on the insulating plate 110, a plurality of thin film transistors 120 connected to the plurality of gate lines GL1 -GLn and the plurality of data lines DL1-DLm, a plurality of pixel electrodes 130 connected to the plurality of thin film transistors 120, and a plurality of fan-out portions including a plurality of data fan-out portions DF1-DF5 and/or a plurality of gate fan-out portions GF1-GF3. In the current exemplary embodiment, ‘m’ and ‘n’ are each natural numbers greater than or equal to 1.

In this exemplary embodiment, the gate fan-out portions GF1-GF3 include a first gate fan-out portion GF1, a second gate fan-out portion GF2, and a third gate fan-out portion GF3. However, in exemplary embodiments, the number of the gate fan-out portions may be increased or decreased in accordance with the number of gate lines GL1-GLn and the number of gate driving chips (not shown), which output the gate signal.

In addition, the data fan-out portions DF1-DF5 include a first data fan-out portion DF1, a second data fan-out portion DF2, a third data fan-out portion DF3, a fourth data fan-out portion DF4, and a fifth data fan-out portion DF5. However, in exemplary embodiments, the number of the data fan-out portions may be increased or decreased in accordance with the number of data lines DL1-DLm and the number of data driving chips (not shown), which output the data signal.

The insulating plate 110 includes a display area DA on which an image is displayed and a peripheral area PA that surrounds the display area DA. The display area DA is divided into a plurality of pixel areas.

The data lines DL1-DLm and the gate lines GL1-GLn are arranged in the display area DA. The data lines DL1-DLm, which transmit a data signal, extend in a first direction D1 and are arranged side by side in a second direction D2. In exemplary embodiments, the second direction D2 is substantially perpendicular to the first direction D1. The gate lines GL1-GLn, which transmit a gate signal, extend in the second direction D2. The gate lines GL1-GLn are insulated from the data lines DL1-DLm.

The plurality of thin film transistors 120 connected to the gate lines GL1-GLn and the data lines DL1-DLm and the plurality of pixel electrodes 130 connected to thin film transistors 120 are arranged in the display area DA in a matrix configuration.

As mentioned above, the thin film transistor substrate 100 further includes a plurality of gate fan-out portions GF1-GF3 to receive the gate signals and to provide the gate signals to the plurality of gate lines GL1-GLn.

Each gate fan-out portion GF1-GF3 includes a plurality of gate fan-out lines GFL1-GFLj (where j is a natural number greater than 1). The gate fan-out lines GFL1-GFLj extend in the second direction D2 and are arranged side by side in the first direction D1. Each gate fan-out line GFL1-GFLj is connected to a corresponding gate line among the plurality of gate lines GL1-GLn to provide the gate signals to the corresponding gate line.

Each data fan-out portion DF1-DF5 includes a plurality of data fan-out lines DFL1-DFLi (where i is a natural number greater than 1). The data fan-out lines DFL1-DFLi extend in the first direction D1 and are arranged side by side in the second direction D2. Each data fan-out line DFL1-DFLi is connected to a corresponding data line among the data lines DL1-DLm in order to provide the data signals to the corresponding data line. In an exemplary embodiment, the first gate fan-out line GFL1 of the first gate fan-out portion GF1 is connected to the first gate line GL1, and the second gate fan-out line GFL2 is connected to the second gate line GL2. Similarly, one data fan-out line DFLk of the first data fan-out portion DF1 is connected to one first data line DLk (k is a natural number satisfying 1≦k≦i).

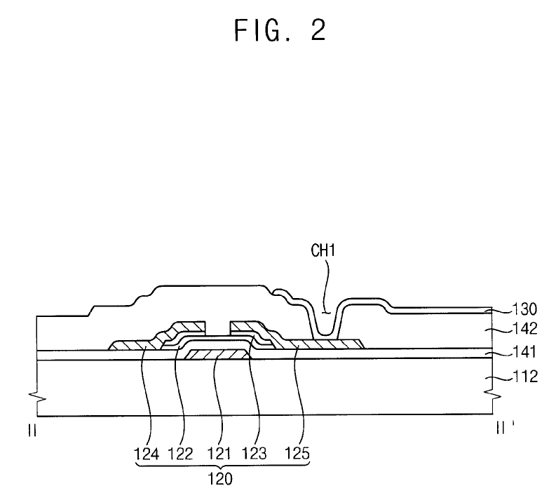

FIG. 2 is a cross-sectional view taken along line II-II′ of FIG. 1. Referring to FIG. 2, each thin film transistor 120 includes a gate electrode 121 arranged on the insulating plate 110, a semiconductor pattern 122 and an ohmic contact pattern 123 that are sequentially arranged above the gate electrode 121, and source and drain electrodes 124 and 125 that are arranged on the ohmic contact pattern 123. In a first pixel area among the pixel areas, the gate electrode 121 is connected to the first gate line GL1 among the gate lines GL1-GLn, and the source electrode 124 is connected to the first data line DL1 among the data lines DL1-DLm. The drain electrode 125 is connected to the pixel electrode 130. In exemplary embodiments, the pixel electrodes 130 may include a transparent conductive material such as indium tin oxide (“ITO”) or indium zinc oxide (“IZO”) and may receive a pixel voltage through the thin film transistors 120.

The thin film transistor substrate 100 further includes a gate insulating layer 141 and a passivation layer 142. The gate insulating layer 141 is arranged on the insulating plate 110 to cover the gate lines GL1-GLn and the gate electrode 121 of the thin film transistor 120. The data lines DL1-DLm and the source and drain electrodes 124 and 125 are arranged on the gate insulating layer 141. The passivation layer 142 is arranged on the insulating plate 110 to cover the data lines DL1-DLm and the source and drain electrodes 124 and 125. A portion of the passivation layer 142 is removed to form a first contact hole CH1 therethrough, such that the drain electrode 125 of the first thin film transistor 120 is connected to the pixel electrode 130 through the first contact hole CH1.

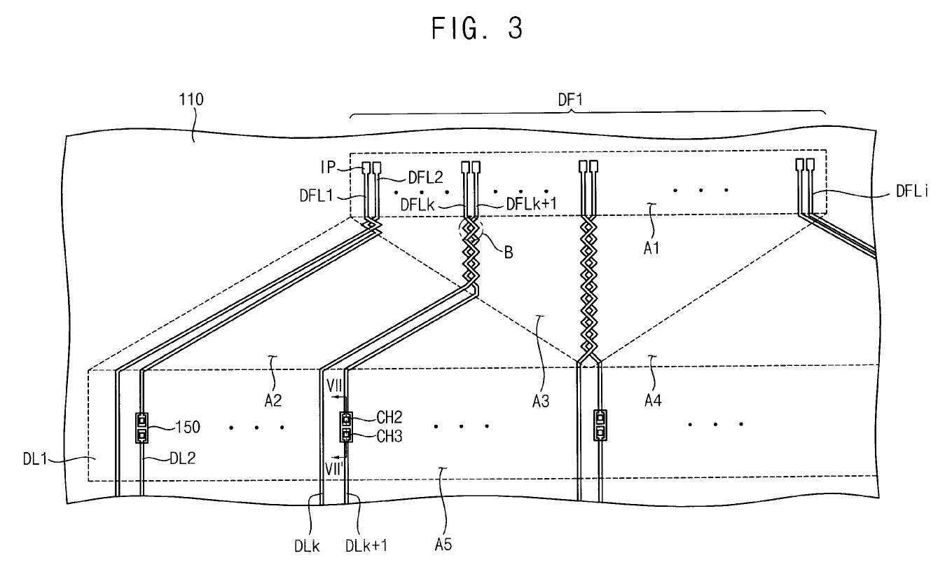

FIG. 3 is an enlarged top view showing portion ‘A’ of FIG. 1. Referring to FIG. 3, a portion of the first data fan-out portion DF1 is shown.

Hereinafter, a portion of the first data fan-out portion DF1 will be described in detail as a representative example, since all of the data fan-out portions DF1-DF5 (see FIG. 1) have the same structure and function.

As described above, the data fan-out lines DFL1-DFLi are arranged in a data fan-out area of the insulating plate 110. The data fan-out area is divided into first to fifth sub areas A1-A5. The first sub area Al may have a rectangular shape. The data driving chip is arranged in the first sub area Al. The second, third, and fourth sub areas A2, A3, and A4 may be positioned below the first sub area Al. Each of the second and fourth sub areas A2 and A4 may have a triangular shape, and the second and fourth sub areas A2 and A4 may be adjacent to each other at a vertex. The third sub area A3 may be surrounded by the first, second, and fourth sub areas A1, A2, and A4. The third sub area A3 may have an inverted triangular shape. The fifth sub area A5 may be positioned below the second, third, and fourth sub areas A2, A3, and A4. The fifth sub area A5 may have a rectangular shape. The fifth sub area A5 may be adjacent to the display area DA. However, the shapes of the first to fifth sub areas Al-A5 of the invention are not limited to the shapes shown in FIG. 3.

A plurality of input pads IP are disposed on the insulating plate 110 at the ends of the data fan-out lines DFL1-DFLi, respectively. The input pads IP are arranged in the first sub area Al to receive the data signal. In the first sub area Al, the plurality of data fan-out lines DFL1-DFLi are spaced apart from each other. In the first sub area Al, each data fan-out line DFL1-DFLi has a linear shape. However, the present invention is not limited thereto.

The data fan-out lines DFL1-DFLi extend toward the third sub area A3 from the first sub area Al, and the data fan-out lines DFL1-DFLi extend toward the second sub area A2 or the fourth sub area A4 after bending in the third sub area A3.

The data fan-out lines DFL1-DFLi include at least a pair of adjacent data fan-out lines. When i is an even number, i/2 pairs of data fan-out lines are formed. When i is an odd number, (i−1)/2 pairs of data fan-out lines are formed. In this exemplary embodiment, each member of the pair of data fan-out lines is formed on a different layer, and the gate insulating layer 141 (see FIG. 2) is disposed between the pair of data fan-out lines.

According to the exemplary embodiments of the invention, the pair of data fan-out lines at least partially overlap with each other. All of the overlapping areas of the pair of data fan-out lines have the same area.

In one exemplary embodiment, at least a portion of at least one of the pair of data fan-out lines has a zigzag shape. In one exemplary embodiment, each of the pair of data fan-out lines has a zigzag shape in the overlapped area. In one exemplary embodiment, the pair of data fan-out lines overlap each other in the third sub area A3. Thus, the total area (the third sub area A3) of the data fan-out lines having the zigzag shape corresponds to an inverted triangular shape on the insulating plate 110.

When each data fan-out line is linear, the lengths and resistances of the data fan-out lines may be different. In other words, at an end portion of the data fan-out portion, the length of the data fan-out line becomes longer than other portions, and a resistance of the data fan-out line also increases. In the middle of the data fan-out portion, the lengths of the data fan-out lines are shorter than the lengths of the data fan-out lines in other portions of the data fan-out portion. Thus, the resistance of the data fan-out lines decreases toward the middle of the data fan-out portion. This resistance difference between data fan-out lines affects a data signal transferring rate, and this may deteriorate a display quality of a display substrate. Thus, at least a portion of the data fan-out lines may be non-linear. This allows length differences and resistance differences between data fan-out lines to be reduced. In this exemplary embodiment, the data fan-out lines DFL1-DFLi have zigzag shapes in the third sub area A3. Thus, the data fan-out line DFL1-DFLi may be regulated to all have the same length.

In this exemplary embodiment, a portion of the data fan-out lines DFL1-DFLi may have a stepped corner configuration. In another exemplary embodiment, a portion of the data fan-out lines DFL1-DFLi may have a rounded corner configuration. In other words, a portion of the data fan-out lines DFL1-DFLi may have a serpentine configuration.

In the first data fan-out portion DF1, the total overlapping area between a pair of data fan-out lines is different for each pair of the data fan-out lines. In one exemplary embodiment, the total overlapping area between a pair of data fan-out lines reaches a maximum in the middle area of the first data fan-out portion DF1. The total overlapping area of a pair of data fan-out lines decreases toward each side from the middle area of the first data fan-out portion DF1. However, the present invention is not limited to the exemplary embodiment described above, and the total overlapping area between a pair of data fan-out lines may be the same for some or all pairs of data fan-out lines.

In one exemplary embodiment, the two adjacent data fan-out lines overlap with each other at an angle of about 90 degrees. The angle is not limited to 90 degrees and may vary between about 40 degrees to 90 degrees as long as two adjacent data fan-out lines overlap with each other.

As described above, the data fan-out lines of at least one pair of data fan-out lines partially overlap with each other, and the area of each overlapping area of the pair of data fan-out lines is the same. Thus, the capacitance between the pair of data fan-out lines that overlap each other may be constant at each overlapping area.

If the data fan-out lines of a pair of data fan-out lines are formed on different layers without the intention to overlap with each other, the pair of data fan-out lines may overlap due to a misalignment between a photo exposure mask and a substrate. This may result in a capacitance between the pair of data fan-out lines. However, a capacitance between a pair of data fan-out lines may not exist in areas where misalignment does not occur. Therefore, the capacitances between pairs of data fan-out lines may vary throughout a substrate, which may deteriorate a display quality.

When portions of a pair of data fan-out lines are intentionally overlapped with each other, the areas of the overlapping areas may be maintained regardless of misalignment. Thus, the display quality deterioration due to the capacitance difference may be reduced.

In one exemplary embodiment, the pair of data fan-out lines includes a first data fan-out line DFLk and a second data fan-out line DFLk+1 adjacent to the first data fan-out line DFLk. The first data fan-out line DFLk extends to one data line DLk of the plurality of data lines. The second data fan-out line DFLk+1 is connected to another data line DLk+1 adjacent to the data line DLk through a second contact hole CH2 and a third contact hole CH3.

In one exemplary embodiment, the first data fan-out line DFLk is arranged on a same layer as the source electrode and the drain electrode, and the second data fan-out line DFLk+1 is arranged on a same layer as the gate electrode.

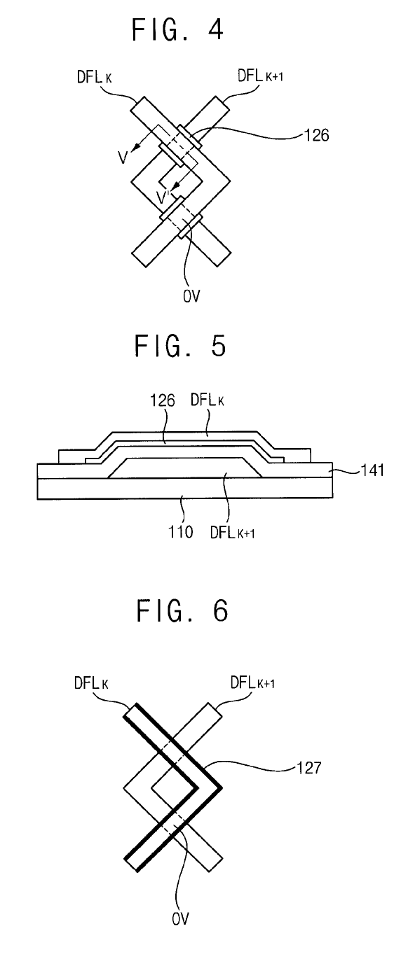

FIG. 4 is an enlarged top view showing portion ‘B’ of FIG. 3

Referring to FIG. 4, the thin film transistor substrate according to one exemplary embodiment of the invention further includes a buffer layer 126. In this exemplary embodiment, the buffer layer 126 is arranged under at least a portion of the first data fan-out lines DFLk. In one exemplary embodiment, the buffer layer 126 is arranged in the area where the first data fan-out line DFLk overlaps with the second data fan-out line DFLk+1.

As shown in FIG. 4, each overlapping area OV of the pair of fan-out lines DFLk and DFLK+1 has the same area.

FIG. 5 is a cross-sectional view taken along line V-V′ of FIG. 4.

Referring to FIG. 5, the first data fan-out line DFLk is insulated from the second data fan-out line DFLk+1 by the gate insulating layer 141. The buffer layer 126is disposed under the first data fan-out line DFLk. The buffer layer 126 is arranged on the same layer as the semiconductor pattern 122 of FIG. 2.

The buffer layer 126 reduces a possibility of an electrical open circuit between the first data fan-out line DFLk and the second data fan-out line DFLk+1. The second data fan-out line DFLk+1 is insulated from the first data fan-out line DFLk by the gate insulating layer 141 (see FIG. 2). Near the portion where the first data fan-out line DFLk overlaps with the second data fan-out line DFLk+1, the first data fan-out line DFLk may be thinner than other portions of the first data fan-out line DFLk where the second data fan-out line DFLk+1 does not exist under the first data fan-out line DFLk. This is because of a taper angle of the second data fan-out line DFLk+1 under the first data fan-out line DFLk. The buffer layer 126 covers the edge of the second data fan-out line DFLk+1 near the overlapping area OV. The buffer layer 126 thus reduces the possibility of electrical open of the first data fan-out line DFLk.

In this exemplary embodiment, the buffer layer 126 may be formed using a different mask from the mask for the first data fan-out line DFLk. When the thin film transistor described in FIG. 2 is formed, the semiconductor pattern 122 may be formed together with the buffer layer 126. The buffer layer 126 may be arranged on the same layer as the semiconductor pattern 122.

As shown in FIG. 4, each overlapping area OV of the pair of fan-out lines DFLk and DFLK+1 has the same area.

FIG. 6 is an enlarged top view showing another exemplary embodiment of data fan-out lines according to the invention.

Referring to FIG. 6, a buffer layer 127 is arranged under the entire first data fan-out line DFLk. In this exemplary embodiment, the buffer layer 127 may be formed using the same mask as the mask for the first data fan-out line DFLk.

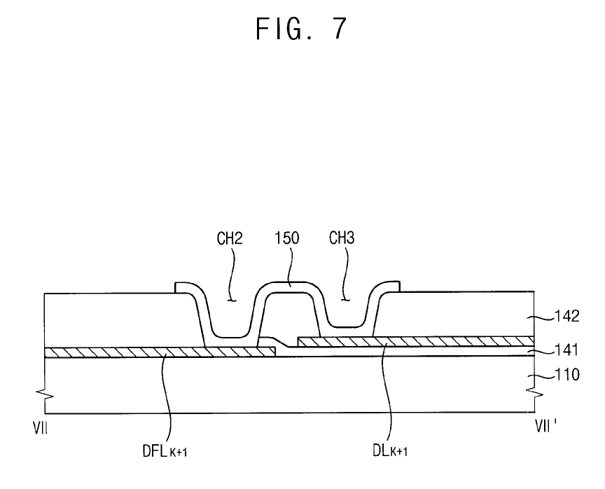

FIG. 7 is a cross-sectional view taken along line VII-VII′ of FIG. 3.

The first data fan-out line DFLk extends to one data line DLk among the data lines DL1-DLm in the fifth sub area A5 (see FIG. 3). Thus, the data line DLk that is arranged on the gate insulating layer 141 extends from the first data fan-out line DFLk in the first data fan-out portion DF1.

In exemplary embodiments, the first data fan-out line DFLk is arranged on the same layer as the data lines DL1-DLm, and the second data fan-out line DFLk+1 is arranged on the same layer as the gate lines GL1-GLn. In alternative exemplary embodiments, the first data fan-out line DFLk is arranged on the same layer as the gate lines GL1-GLn, and the second data fan-out line DFLk+1 is arranged on the same layer as the data lines DL1-DLm.

The second data fan-out line DFLk+1 is connected to another data line DLk+1 among the data lines DL1-DLm in the fifth sub area A5 (see FIG. 3). The second data fan-out line DFLk+1 is connected to the data line DLk+1 by a connection member 150 through a second contact hole CH2 and a third contact hole CH3. In another exemplary embodiment, the third contact hole CH3 is omitted. The data line DLk+1 extends to the second data fan-out line DFLk+1 and the data line DLk+1 directly contacts the second data fan-out line DFLk+1 through the second contact hole CH2.

The connection member 150 is arranged on the passivation layer 142. The connection member 150 may be formed through a process similar to that used to form the pixel electrodes 130 of FIG. 2, and the connection member 150 may include the same or a substantially similar material as the pixel electrodes 130.

As described above, two adjacent fan-out lines at least partially overlap with each other, and each overlapping area of the pair of fan-out lines has the same area even if misalignment occurs between the pair of fan-out lines. Thus, the capacitances between pairs of two adjacent fan-out lines may be constant. As a result, the display device may have improved display quality.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A thin film transistor substrate, comprising:
an insulating plate;
a plurality of fan-out lines arranged on the insulating plate, the fan-out lines comprising at least a pair of adjacent fan-out lines, wherein the adjacent fan-out lines at least partially overlap with each other, and each overlapping area of the adjacent fan-out lines has the same area;
a plurality of signal lines connected to the plurality of fan-out lines; and
a plurality of thin film transistors connected to the plurality of signal lines.

2. The thin film transistor substrate of claim 1, wherein at least a portion of the adjacent fan-out lines has a zigzag shape.

3. The thin film transistor substrate of claim 2, wherein each of the adjacent fan-out lines has the zigzag shape in the overlapping area.

4. The thin film transistor substrate of claim 1, wherein each thin film transistor comprises a gate electrode, a semiconductor pattern, a gate insulating layer disposed between the gate electrode and the semiconductor pattern, a source electrode, and a drain electrode, the source electrode and the drain electrode being connected to the semiconductor pattern, and wherein a first fan-out line of the pair of adjacent fan-out lines is arranged on the same layer as the gate electrode, and a second fan-out line of the pair of adjacent fan-out lines is arranged on the same layer as the source electrode and the drain electrode.

5. The thin film transistor substrate of claim 4, further comprising a buffer layer arranged under at least a portion of the second fan-out line.

6. The thin film transistor substrate of claim 5, wherein the buffer layer is arranged in the overlapping area.

7. The thin film transistor substrate of claim 5, wherein the buffer layer is arranged under the entire second fan-out line.

8. The thin film transistor substrate of claim 5, wherein the buffer layer is arranged on the same layer as the semiconductor pattern.

9. The thin film transistor substrate of claim 1, wherein a first fan-out line of the pair of adjacent fan-out lines extends to a first signal line of the plurality of signal lines, and a second fan-out line of the pair of adjacent fan-out lines is connected to a second signal line, which is adjacent to the first signal line, through a contact hole.

10. A thin film transistor substrate, comprising:
an insulating plate;
a plurality of gate fan-out lines arranged on the insulating plate;
a plurality of data fan-out lines arranged on the insulating plate;
a plurality of gate lines connected to the gate fan-out lines;
a plurality of data lines connected to the data fan-out lines; and
a plurality of thin film transistors connected to the gate lines and the data lines,
wherein at least one of the gate fan-out lines and the data fan-out lines comprises at least one pair of adjacent fan-out lines, and at least a portion of the adjacent fan-out lines has a zigzag shape.

11. The thin film transistor substrate of claim 10, wherein the adjacent fan-out lines partially overlap with each other, and each overlapping area of the adjacent fan-out lines has the same area.

12. The thin film transistor substrate of claim 11, wherein each of the adjacent fan-out lines has the zigzag shape in the overlapping area.

13. The thin film transistor substrate of claim 10, wherein a region where the fan-out lines having the zigzag shape has a substantial inverted triangular shape.

14. The thin film transistor substrate of claim 13, wherein the sum of overlapping areas between pairs of fan-out lines is maximum in a middle area of the region of the inverted triangular shape.

15. The thin film transistor substrate of claim 10, wherein the adjacent fan-out lines overlap with each other at an angle of about 90 degrees.

16. The thin film transistor substrate of claim 10, wherein capacitance between the adjacent fan-out lines is the same at each overlapping area.

17. The thin film transistor substrate of claim 10, wherein each thin film transistor comprises a gate electrode, a semiconductor pattern, a gate insulating layer interposed between the gate electrode and the semiconductor pattern, a source electrode, and a drain electrode, the source electrode and the drain electrode being connected to the semiconductor pattern, and wherein a first fan-out line of the pair of adjacent fan-out lines is arranged on the same layer as the gate electrode, and a second fan-out line of the pair of adjacent fan-out lines is arranged on the same layer as the source electrode and the drain electrode.

18. The thin film transistor substrate of claim 17, further comprising a buffer layer arranged under at least a portion of the second fan-out line.

19. A method of manufacturing a thin film transistor substrate, comprising:
forming a plurality of gate electrodes, a plurality of gate lines connected to the gate electrodes, a first gate fan-out line extending to one of the gate lines, and a first data fan-out line;
forming a gate insulating layer on the gate electrodes, the gate lines, the first gate fan-out line, and the first data fan-out line;
forming a plurality of semiconductor patterns on the gate insulating layer;
forming a plurality of source electrodes, a plurality of drain electrodes, and a plurality of data lines connected to the source electrodes, a second gate fan-out line adjacent to the first gate fan-out line and connected to one of the gate lines, and a second data fan-out line adjacent to the first data fan-out line and extending to one of the data lines,
wherein the first data fan-out line is connected to one of the data lines, and wherein at least a portion of the second gate fan-out line overlaps with at least a portion of the first gate fan-out line; and
forming a passivation layer on the source electrodes, the drain electrodes, the data lines, the second gate fan-out line, and the second data fan-out line.

20. The method of claim 19, further comprising forming a pixel electrode connected to the drain electrode, and a connection member on the passivation layer.

21. The method of claim 19, wherein the connection member connects the second data fan-out line and one of the data lines.
